(19) United States
(12) Patent Application Publication
(10) Pub. No.: US 2024/0371714 A1
(43) Pub. Date: Nov. 7, 2024

(54) CHIP PACKAGE WITH A GLASS INTERPOSER

(71) Applicant: Advanced Micro Devices, Inc., Santa Clara, CA (US)

(72) Inventors: Deepak Vasant KULKARNI, Austin, TX (US); Raja SWAMINATHAN, Austin, TX (US); Sri Ranga Sai BOYAPATI, Austin, TX (US); Brett P. WILKERSON, Austin, TX (US)

(21) Appl. No.: 18/644,958

(22) Filed: Apr. 24, 2024

Related U.S. Application Data
(60) Provisional application No. 63/463,259, filed on May 1, 2023.

(51) Int. Cl. H01L 23/15; H01L 21/683; H01L 23/00; H01L 23/498; H01L 25/00; H01L 25/065

(52) U.S. Cl. CPC H01L 23/15; H01L 21/6836; H01L 23/49833; H01L 23/49838; H01L 24/16; H01L 25/0655; H01L 25/50; H01L 2224/16225; H01L 2924/1815

(57) ABSTRACT

A chip package having a package substrate including a top surface. A first chip module and a second chip module are mounted above the top surface of the package substrate. A first interposer is disposed between the package substrate and the first and second chip modules and includes a glass interposer. The first interposer couples the first and second chip modules to the package substrate. An interconnect bridge is disposed in a cavity of the glass interposer. The interconnect bridge includes circuitry that connects a circuitry of the first chip module to a circuitry of the second chip module.

### CROSS REFERENCE TO RELATED APPLICATION

This application claims priority to the U.S. Provisional Patent Application Ser. No. 63/463,259 filed May 1, 2023 of which is incorporated herein by reference in its entirety.

### TECHNICAL FIELD

Examples of the present disclosure generally relate to a chip package, and in particular, to a chip package having an integrated circuit (IC) die disposed on a glass interposer.

### BACKGROUND

Electronic devices, such as tablets, computers, copiers, digital cameras, smart phones, control systems and automated teller machines, among others, often employ electronic components which leverage chip packages for increased functionality and higher component density. Conventional chip packaging schemes often utilize a package substrate, often in conjunction with a through-silicon-via (TSV) interposer, to enable a plurality of integrated circuit (IC) dies to be mounted to a single package substrate. The IC dies may include memory, logic or other IC devices.

Wafer-level multi-chip packaging technology has been develop to incorporate multiple dies side-by-side on a silicon interposer in order to achieve a better interconnect density and performance. The individual chips are bonded through micro-bumps on a silicon interposer forming a chip-on-wafer (CoW). The CoW is then subsequently thinned such that through silicon via perforations are exposed. This is followed by C4 bump formation and singulation. The CoWoS package is completed through bonding to a package substrate. However, wafer based packaging for large chip modules has limited scalability due to the reticle limit.

Therefore, a need exists for an improved chip package that is scalable for larger chip modules.

### SUMMARY

A chip package having a first chip module and a second chip module mounted above a top surface of a package substrate. A first interposer is disposed between the package substrate and the first and second chip modules and includes a glass interposer. The first interposer couples the first and second chip modules to the package substrate. An interconnect bridge is disposed in a cavity of the glass interposer. The interconnect bridge includes circuitry that connects a circuitry of the first chip module to a circuitry of the second chip module. In one example, the first interposer includes an interconnect routing structure disposed on a top surface of the glass interposer and below the first and second chip modules. The interconnect routing structure may include one or more redistribution layers having circuitry that connects the circuitry of the interconnect bridge to the circuitry of first and second chip modules. The one or more redistribution layers also include circuitry that connects the circuitry of the first and second chip modules to a circuitry of the package substrate.

In another example, a method for fabricating a chip package is provided that includes mounting an interconnect bridge in a cavity of a first interposer, the first interposer having a glass interposer. At least one integrated circuit die is mounted to a second interposer to form a first integrated circuit chip module. For example, the first chip module may include first and second circuit dies mounted to the second interposer. Similarly, at least one integrated circuit die is mounted to a third interposer to form a second integrated circuit chip module. For example, the second chip module may include third and fourth circuit dies mounted to a second interposer. The first and second chip modules are mounted on the first interposer. A circuitry of the interconnect bridge connects a circuitry of the first chip module to a circuitry of the second chip module. The first and second chip modules and the first interposer are mounted on a package substrate.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a schematic sectional view of a chip package having an interposer made of glass and an interconnect bridge disposed in the interposer.

FIG. 2 is a schematic partial view of a portion of the chip package of FIG. 1 detailing the interposer.

FIG. 3 is a flow diagram of a method for fabricating a chip package having a chip package having a glass interposer and an interconnect bridge coupling a first chip module to a second chip module.

To facilitate understanding, identical reference numerals have been used, where possible, to designate identical elements that are common to the figures. It is contemplated that elements of one example may be beneficially incorporated in other examples.

### DETAILED DESCRIPTION

Described herein is an improved chip package and methods for fabricating the same. The improved chip package utilizes a glass interposer to take advantage of the geometry of a glass panel for chip packaging. Two chip modules, each including a plurality of dies, are mounted on the glass interposer. In turn, the glass interposer is mounted on a package substrate. The two chip modules are coupled via an interconnect bridge disposed in the glass interposer. In some embodiments, a photonic connector is mounted on the glass interposer.

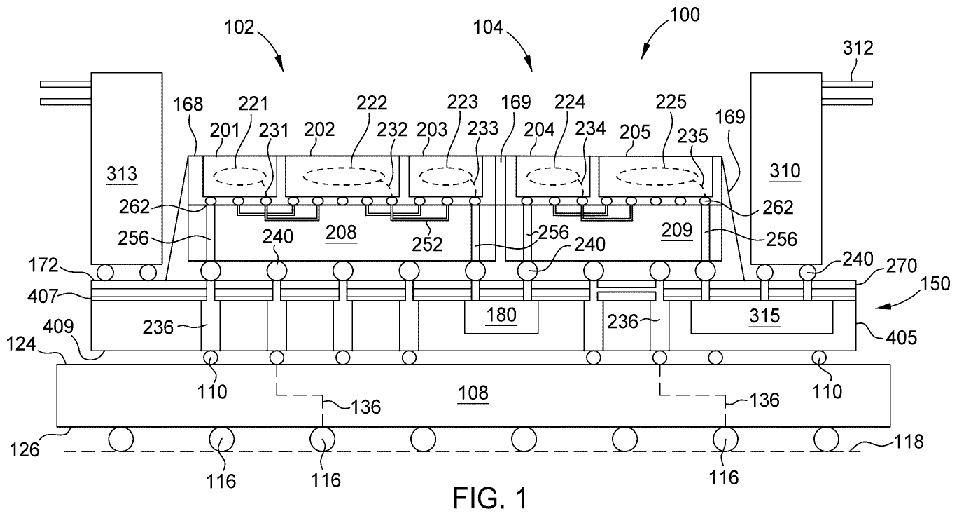

Turning now to FIG. 1, FIG. 1 is a schematic sectional view of a chip package 100 having a first chip module 102 and a second chip module 104, a first interposer 150, and a package substrate 108. The first and second chip modules 102, 104 are laterally disposed on a top surface 172 of the first interposer 150. In one embodiment, the first interposer 150 includes a glass interposer 405. The first interposer 150 is disposed above the package substrate 108. In one embodiment, the glass interposer 405 may be manufactured from a glass panel. The glass interposer 405 may have a thickness range from 200 μm to 1500 μm, such as from 300 μm to 400 μm or from 800 μm to 1200 μm.

In the example depicted in FIG. 1, the first chip module 102 includes a first IC die 201, a second IC die 202, and a third IC die 203 laterally disposed on a second interposer 208. The second chip module 104 includes a fourth IC die 204 and a fifth IC die 205 laterally disposed on a third interposer 209. In this example, the first IC die 201 and the fourth IC die 204 may be core dies (e.g., logic or processor die, such as a field programmable gate array, application specific integrated circuit (ASIC), or other digital signal processing chip). The second IC die 202, the third IC die 203, and the fifth IC die 205 may be memory devices such as high band-width memory (“HBM”). However, it is contemplated the IC dies 201-205 may be combinations of any suitable logic and memory devices, such as field programmable gate arrays (FPGA), application-specific integrated circuits (ASICs), memory devices, such as high band-width memory (HBM), optical devices, processors or other IC logic or memory structures. One or more of the IC dies 206 may optionally include optical devices such as photo-detectors, lasers, optical sources, and the like.

The second and third interposers 208, 209 may be a silicon interposer, organic interposer, ceramic interposer, glass interposer or suitable stack of materials through which interconnect routing may be disposed. A bottom surface of the second interposer 208 and a bottom surface of the third interposer 209 faces a top surface 172 of the first interposer 150.

Although five IC dies 201-205 are shown in FIG. 1, the total number of IC dies disposed on the second and third interposers 208, 209 may range from two to as many as can be fit within the chip modules 102, 104. Additionally, one or more dies may be stacked directly on one or more of the IC dies 201-205. Filler material 168 may be disposed between the IC dies 201-205 and the second and third interposers 208, 209 to provide structural integrity to the chip modules 102, 104.

Each of the IC dies 201-205 includes an internal functional circuitry 221-225 that is coupled by internal routings 231-235 to contact pads (not shown) exposed on a bottom surface of the IC dies 201-205. The contact pads exposed on the bottom surface of the IC dies 201-205 are coupled by interconnects 262, for example solder microbumps, to internal routings 252, 256 of the internal circuitry 238 of their respective interposers 208, 209. The internal routings 252 provide communication between IC dies 201-205, for example, between the first IC die 201 and the second IC die 202 or between the fourth IC die 204 and fifth IC die 205. The internal routings 256 provide communication between the IC dies 201-205 and the first interposer 150, for example, between the first IC die 201 and the first interposer 150 or between the fourth IC die 204 and the first interposer 150. The interconnects 262 provide mechanical and electrical connection between the IC dies 201-205 and the first and second interposers 208, 209. Filler material 169 may be disposed between the chip modules 102, 104 and first interposer 150 to provide structural integrity.

A bottom surface of the second and third interposers 208, 209 faces and overlaps the top surface 172 of the first interposer 150. Interconnects 240, which may be for example controlled collapse chip connection (C4 balls), couple a portion of the internal routings 256 of the second and third interposers 208, 209 to the circuitry 236 formed through the first interposer 150. The interconnects 240 provide mechanical and electrical connections between the second and third interposers 208, 209 and the first interposer 150. In one embodiment, the circuitry 236 of the first interposer 150 includes circuitry through one or more redistribution layers 270 and the glass interposer 405 of the first interposer 150. In one example, two redistribution layers 270 are formed on the top surface 407 of the glass interposer 405. The redistribution layers 270 may be used to extend the pitch of the interconnects 240.

In one embodiment, a portion of the internal routings 256 of the second and third interposers 208, 209 is connected to an interconnect bridge 180 disposed in the first interposer 150. The interconnect bridge 180 provides communication between the first chip module 102 and the second chip module 104. In one example, the interconnect bridge 180 is an embedded multi-die interconnect bridge (EMIB) having high density routing. In another example, the interconnect bridge 180 is a silicon-based integrated circuit die having internal high density solid state routing to provide communication between first chip module 102 and the second chip module 104. In some examples, the interconnect bridge 180 configured as a silicon-based integrated circuit die has only solid state routing and no active circuit elements, such as transistors and the like.

A bottom surface 409 of the first interposer 150 faces and overlaps the top surface 124 of the package substrate 108. Interconnects 110, which may be for example controlled collapse chip connection (C4 balls), couple a portion of the circuitry 236 of the first interposer 150 to circuitry 136 formed through the package substrate 108. The interconnects 110 provide mechanical and electrical connections between the package substrate 108 and the first interposer 150.

Some of the circuitry 136 formed in the package substrate 108 terminates at contact pads (not shown) exposed on a bottom surface 126 of the package substrate 108 that faces away from the first interposer 150. Solder balls 116 (e.g., ball grid array (BGA)) are disposed on the contact pads exposed on the bottom surface 126 of the package substrate 108. The solder balls 116 are utilized to couple the chip package 100 to a printed circuit board 118 (shown in phantom) to form an electronic device.

In one embodiment, the chip package 100 includes a photonic connector 310 attached to the first interposer 150. The photonic connector 310 includes a fiber optic cable 312 for connection to an optical device. A bottom surface of photonic connector 310 faces and overlaps the top surface 172 of the first interposer 150. Interconnects 240 couple circuitry of the photonic connector 310 to circuitry 236 formed through the first interposer 150. The interconnects 240 provide mechanical and electrical connections between the photonic connector 310 and the first interposer 150. In one embodiment, an electric integrated circuit (EIC) 315 disposed in the first interposer 150 provides communication between the second chip module 104 and the photonic connector 310. The EIC 315 may function as an electrical to optical converter. In some embodiments, a co-package cable 313 is mounted on the first interposer 150.

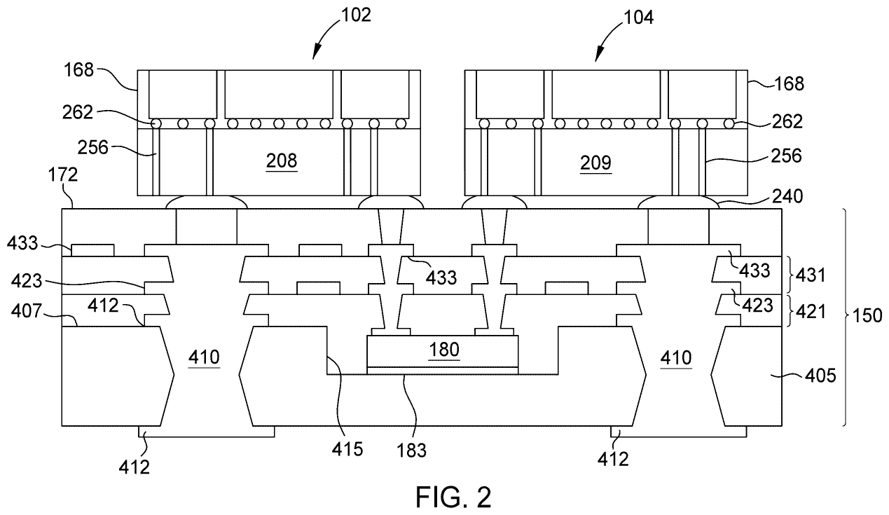

In one embodiment, the first interposer 150 and the chip modules 102, 104 may be individually manufactured and then assembled together to form the chip package 100. FIG. 2 illustrates an enlarged, partial view of an exemplary embodiment of the first interposer 150. The first interposer 150 includes a glass interposer 405 provided with a plurality of vias 410. In some examples, the vias 410 are formed through the glass interposer 405, which may have a thickness from about 300 μm to about 400 μm. Pads 412 are formed on the top and bottom surfaces of the glass interposer 405. An interconnect bridge 180 is disposed in a cavity 415 formed in the glass interposer 405. In one example, the interconnect bridge 180 is an embedded multi-die interconnect bridge (EMIB) having high density routing. The interconnect bridge 180 may be attached to the glass interposer 405 using any suitable mechanism, such as die mounting tape 183.

An interconnect routing structure is formed on the exposed surfaces of the glass interposer 405. In this example, the interconnect routing structure is embodied as one or more redistribution layers, such as a first redistribution layer 421 and a second redistribution layer 431. Each of the redistribution layers 421, 431 may include three or more patterned metal layers disposed between dielectric layers. In one example, the metal layers are plated copper and the dielectric layers are an oxide. The patterned metal layers are used to form pads 423, 433 and lines that are interconnected by vias to form electrical routing circuitry through the redistribution layers 421, 431. The electrical routing circuitry through the redistribution layers 421, 431 is utilized to connect the functional circuitry 236 of the first interposer 150 to the internal routings 256 of the first and second chip modules 102, 104. For example, one pad 433 of the routing circuitry of the second redistribution layer 431 terminates at the solder interconnects 240, while the routing circuitry of the second redistribution layer 431 connects the pad 433 to the pad 423 of the first redistribution layer 421. In turn, the routing circuitry of the first redistribution layer 421 connects the pad 423 with the pad 412 of the glass interposer 405. The redistribution layers 421, 431 also connect the internal routings 256 of the first and second chip modules 102, 104 to the functional circuitry of the interconnect bridge 180. In this manner, the redistribution layers 421, 431 may be formed directly on the exposed top surface of the glass interposer 405 without any intervening solder connections. The solder interconnects 240 are plated or otherwise formed on the pads 433 of the second redistribution layer 431.

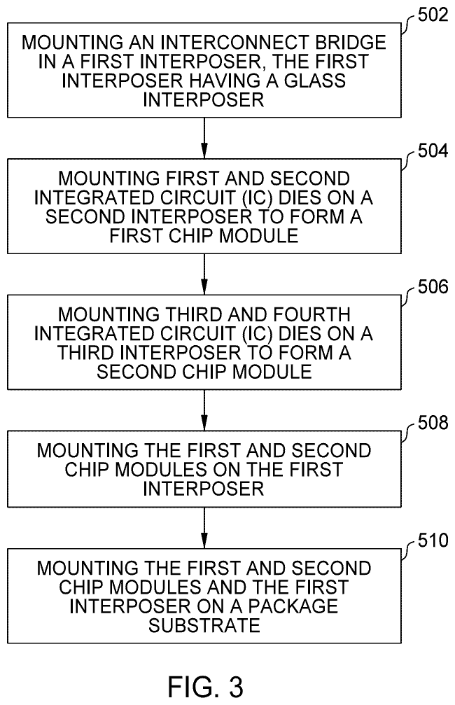

FIG. 3 is a flow diagram of a method 500 for fabricating a chip package having a glass interposer and an interconnect bridge coupling a first and second chip modules. The method 500 may be utilized to fabricate the chip package 100 described above, or other similar chip packages.

The method 500 begins at operation 502 where an interconnect bridge 180 is mounted in a cavity 415 of the first interposer 150. In this example, the first interposer 150 includes a glass interposer 405. The interconnect bridge 180 is an embedded multi-die interconnect bridge (EMIB) having high density routing. In this example, the interconnect bridge 180 is disposed in a cavity formed in the glass interposer 405. The glass interposer 405 may have a thickness from about 300 μm to about 400 μm and a plurality of vias 410 formed through the glass interposer 405. In some embodiments, an interconnect routing structure is formed on the exposed surfaces of the glass interposer 405 and connect to the vias 410. In this example, the interconnect routing structure is embodied as one or more redistribution layers, such as two redistribution layers 421, 431. In some embodiments, the glass interposer 405 may have a thickness from about 800 μm to 1,200 μm. For these thicker glass interposers, a plurality of pillar vias are formed to a desired depth in the glass interposer 405, instead of through the glass interposer 405.

At operation 504, the first and second integrated circuit (IC) dies 201, 202 are mounted to the second interposer 208 via interconnects 262 to form a first chip module 102. At operation 504, the filler material 168 may also be disposed on the second interposer 208 to fill the inter-die gap laterally defined between the IC dies 201, 202. In some embodiment, three or more dies (e.g., third IC die 203) may be mounted to the second interposer 208.

At operation 506, the fourth and fifth integrated circuit (IC) dies 204, 205 are mounted to the second interposer 208 via interconnects 262 to form a second chip module 104. At operation 506, the filler material 168 may also be disposed on the third interposer 209 to fill the inter-die gap laterally defined between the IC dies 204, 205. In some embodiment, three or more dies may be mounted to the third interposer 209. It is contemplated that operations 504 and 506 may be performed before operation 502.

At operation 508, the first and second chip modules 102, 104 are mounted on the first interposer 150. At operation 508, the solder interconnects 240 electrically and mechanically couple the first and second chip modules 102, 104 to the first interposer 150. In this example, the first and second chip modules 102, 104 are mounted on the interconnect routing structure of the first interposer 150, e.g., mounted above the two redistribution layers 421, 431. The first and second chip modules 102, 104 are electrically connected to the circuitry of the interconnect bridge 180. The interconnect bridge 180 provides communication between the first and second chip modules 102, 104. In the embodiments where the glass interposer 405 includes pillar vias instead of through glass vias, a grinding process may be performed on the glass interposer 405 to reveal the pillar via for connection to the package substrate 108.

At operation 510, the first and second chip modules 102, 104 and the first interposer 150 are mounted on the package substrate 108. At operation 510, interconnects 110 electrically and mechanically couple the first and second chip modules 102, 104 and the first interposer 150 to the package substrate 108. In one embodiment, solder balls 116 are disposed on the bottom surface 126 of the package substrate 108 to form the chip package 100. The solder balls 116 may be utilized to electrically and mechanically couple the chip package 100 to a printed circuit board 118.

At operation 512, optionally, a photonic connector 310 is mounted to the top surface of the first interposer 150. At operation 512, an electric integrated circuit 315 is disposed in the glass interposer 405 of the first interposer 150. The electric integrated circuit 315 couples the photonic connector 310 to the second chip module 104. The photonic connector 310 may include a fiber optic cable 312 for connection to an optical device. It is noted that operation 512 may be performed before operations 508 or 510.

An improved chip package and methods for fabricating the same have been described that provides the chip package to include a first interposer made of glass. In this respect, the glass interposer may be manufactured from a glass panel, which advantageously provides a scalable solution for large reticle modules based on the geometry, e.g., rectangular including square, of the glass panel. The chip package described above advantageously enables photonic connectors to be included in the chip package and an electric integrated circuit die to be embedded in the glass interposer.

While the foregoing is directed to specific examples, other and further examples may be devised without departing from the basic scope thereof, and the scope thereof is determined by the claims that follow.

What is claimed is:

1. A chip package comprising:
a package substrate having a top surface;
a first chip module mounted above the top surface of the package substrate;
a second chip module mounted above the top surface of the package substrate;
a first interposer disposed between the package substrate and the first and second chip modules and includes a glass interposer, the first interposer coupling the first and second chip modules to the package substrate; and
an interconnect bridge disposed in a cavity of the glass interposer, the interconnect bridge having circuitry that connects a circuitry of the first chip module to a circuitry of the second chip module.

2. The chip package of claim 1, wherein the first interposer further comprises an interconnect routing structure disposed on a top surface of the glass interposer and below the first and second chip modules.

3. The chip package of claim 2, wherein the interconnect routing structure comprises one or more redistribution layers having circuitry that connects the circuitry of the interconnect bridge to the circuitry of first and second chip modules.

4. The chip package of claim 2, wherein the interconnect routing structure comprises one or more redistribution layers having circuitry that connects the circuitry of the first and second chip modules to a circuitry of the package substrate.

5. The chip package of claim 1, further comprising a photonic connector mounted on the top surface of the first interposer.

6. The chip package of claim 5, further comprising an electric integrated circuit disposed in the first interposer, the electric integrated circuit providing communication between the second chip module and the photonic connector.

7. The chip package of claim 5, wherein the photonic connector includes a fiber optic cable.

8. The chip package of claim 1, wherein the first chip module comprises a first die mounted to a second interposer and the second chip module comprises a second die mounted to a third interposer.

9. The chip package of claim 8, wherein the first chip module further comprises a third die mounted to the second interposer and the second chip module further comprises a fourth die mounted to the third interposer.

10. The chip package of claim 1, wherein the interconnect bridge comprises high density routing.

11. A chip package comprising:
a package substrate having a top surface;
a first chip module mounted above the top surface of the package substrate;
a second chip module mounted above the top surface of the package substrate;
a first interposer disposed between the package substrate and the first and second chip modules and includes a glass interposer, the first interposer coupling the first and second chip modules to the package substrate;
a photonic connector mounted on the top surface of the first interposer; and
an electric integrated circuit disposed in the first interposer, the electric integrated circuit providing communication between the second chip module and the photonic connector.

12. The chip package of claim 11, further comprising an interconnect bridge disposed in the glass interposer, the interconnect bridge having circuitry that connects a circuitry of the first chip module to a circuitry of the second chip module.

13. The chip package of claim 12, wherein the first interposer further comprises a redistribution layer disposed on a top surface of the glass interposer and below the first and second chip modules, the redistribution layer includes circuitry that connects the circuitry of the interconnect bridge to the circuitry of first and second chip modules.

14. A method for fabricating a chip package, the method comprising:
mounting an interconnect bridge in a cavity of a first interposer, the first interposer having a glass interposer;
mounting first and second integrated circuit (IC) dies to a second interposer to form a first chip module;
mounting third and fourth integrated circuit (IC) dies to a third interposer to form a second chip module;
mounting the first and second chip modules on the first interposer;
connecting a circuitry of the first chip module to a circuitry of the second chip module using a circuitry of the interconnect bridge; and
mounting the first and second chip modules and the first interposer on a package substrate.

15. The method of claim 14, further comprising mounting a photonic connector to the first interposer.

16. The method of claim 15, further comprising mounting an electric integrated circuit in the first interposer, the electric integrated circuit coupling the photonic connector to the second chip module.

17. The method of claim 14, wherein the glass interposer of the first interposer is manufactured from a glass panel.

18. The method of claim 14, further comprising forming an interconnect routing structure on a top surface of the glass interposer of the first interposer.

19. The method of claim 18, wherein forming the interconnect routing structure comprises forming one or more redistribution layers on the glass interposer.

20. The method of claim 14, wherein mounting the interconnect bridge comprises attaching the interconnect bridge using die mounting tape.
